(19) United States
(12) Patent Application Publication
(10) Pub. No.: US 2011/0233598 A1
(43) Pub. Date: Sep. 29, 2011

(54) LIGHT EMITTING DIODE PACKAGE AND MANUFACTURING METHOD THEREOF

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 12/848,213

(22) Filed: Aug. 1, 2010

(30) Foreign Application Priority Data
Mar. 26, 2010 (TW) 99108996

(51) Int. Cl. H01L 33/62; H01L 33/48

(52) U.S. Cl. 257/99; 438/26; 257/E33.056; 257/E33.066

(57) ABSTRACT

A light emitting diode package includes a metallic substrate, a light emitting diode chip, and a buffer layer. The light emitting diode chip is arranged on the metallic substrate. The buffer layer is located between and connected to the metallic substrate and the light emitting diode chip. The buffer layer includes a base material and a number of conducting particles essentially mixed in the base material. The base material is soft epoxy. Each of the conducting particles includes a resin core and a metallic layer formed on an exterior surface of the resin core. The conducting particles are configured for electrically connecting the light emitting diode chip to the metallic substrate.

### TECHNICAL FIELD

The disclosure generally relates to light emitting diode (LED) packages, and particularly to an LED package having a reliable performance and a method for making the LED package.

### DESCRIPTION OF RELATED ART

In recent years, due to excellent light quality and high luminous efficiency, light emitting diodes (LEDs) have increasingly been used to substitute for cold cathode fluorescent lamps (CCFL), incandescent bulbs and fluorescent lamps as a light source of an illumination device.

A typical LED is generally manufactured by arranging an LED chip on a substrate, and following by applying package process to the LED chip on the substrate. The substrate is generally made of metal. In operation, the substrate is used to apply electric current to the LED chip, as well as transfer heat from the LED chip. Generally, a base material of an LED chip is different from a base material of the substrate. Accordingly, a coefficient of thermal expansion (CTE) of the LED chip is different from that of the substrate. The difference of the thermal expansion between the LED chip and the substrate may result in thermal stress and heat deformation between the LED chip and the substrate when the LED chip generates heat. Thus, performance of the LED is unreliable.

Therefore, what is needed is an LED package and a method for making an LED package that can overcome the described limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is cross-section of an LED package, in accordance with an exemplary embodiment.

FIG. 2 is cross-section of a conducting particle of the LED package of FIG. 1.

FIG. 3 is a flow chart of a method for manufacturing the LED package of FIG. 1.

FIG. 4 is cross-section of a metallic substrate and a buffer layer used in the method of FIG. 3.

FIG. 5 is cross-section of an LED chip used in the method of FIG. 3.

FIG. 6 is similar to FIG. 4, but showing the LED chip of FIG. 5 is formed on the buffer layer.

FIG. 7 is similar to FIG. 6, but showing an electrode pad is formed on the LED chip.

FIG. 8 is similar to FIG. 7, but showing a through hole is defined in the metallic substrate and filled with conducting material and insulating material.

FIG. 9 is cross-section of an LED using the LED package of FIG. 8.

### DETAILED DESCRIPTION

Embodiment of the LED package and the method for manufacturing LED package will now be described in detail below and with reference to the drawings.

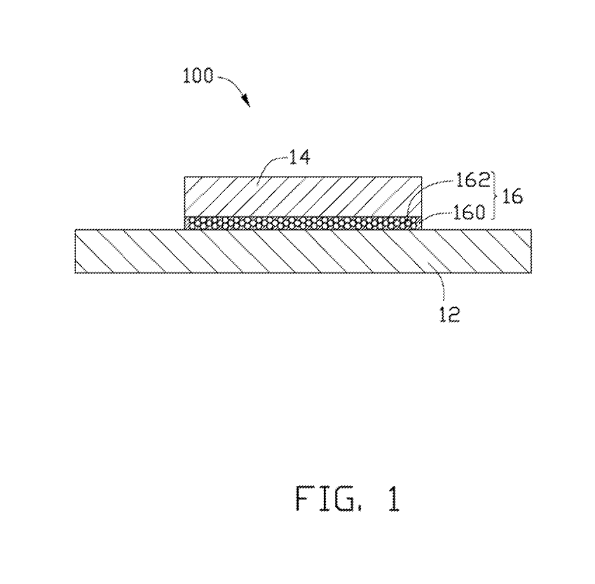

Referring to FIG. 1, an LED package 100 in accordance with an exemplary embodiment is shown. The LED package 100 includes a metallic substrate 12, an LED chip 14, and a buffer layer 16.

The metallic substrate 12 can be made of metal, such as aluminum, copper, an alloy thereof, or another suitable metal or alloy. In this embodiment, the metallic substrate 12 is made of a copper alloy. In addition, the metallic substrate 12 has a generally cylindrical shape or a general shape of a disk.

The LED chip 14 can be essentially made of nitrides such as GaN, or another suitable semiconductor material, such as phosphide or arsenide. The LED chip 14 is arranged on the metallic substrate 12. In this embodiment, the buffer layer 16 is located between the LED chip 14 and the metallic substrate 12, and the buffer layer 16 is configured for connecting the LED chip 14 to the metallic substrate 12.

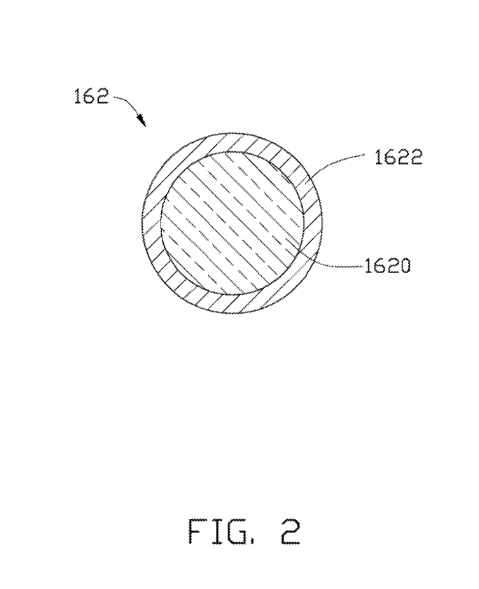

Referring also to FIG. 2, the buffer layer 16 includes a base material 160 and a number of conducting particles 162 essentially mixed in the base material 160. In this embodiment, the base material 160 can be soft epoxy. Each conducting particle 162 includes a resin core 1620 and a metallic layer 1622 formed on an exterior surface of the resin core 1620 (see FIG. 2). The resin core 1620 is compressible. The material of the resin core 1620 can for example be acrylic resin. A material of the metallic layer 1622 can be nickel, gold, silver, tin, or another suitable material. In this embodiment, the metallic layer 1622 can be made of alloy containing tin and gold. The conducting particle 162 has a spherical shape. In this embodiment, the conducting particles 162 overlap with one another, and a portion of the conducting particles 162 contacts with the metallic substrate 12 and the buffer layer 16. In alternative embodiment, the conducting particles 162 may be spaced apart from one another, and each of the conducting particles 162 contacts with both of the metallic substrate 12 and the buffer layer 16.

One advantage of the LED package 100 is that the LED package 100 is equipped with the buffer layer 16 with base material 160 and conducting particles 162. The conducting particles 162 can be used to electrically connect the LED chip 14 to the metallic substrate 12. In operation, the metallic substrate 12 can be used to apply electric current to the LED chip 14. The LED chip 14 emits light and generates heat. The heat is transferred to the metallic substrate 12 through the buffer layer 16, and is dissipated outside of the LED package 100. In this embodiment, the buffer layer 16 allows the LED chip 14 and the metallic substrate 12 to be slightly expandable towards each other when heated and expanded, without subsequently causing the LED chip 14 and the metallic substrate 12 to exert significant pressure to each other. In this way, a reliable and consistent performance of the LED package 100 is ensured.

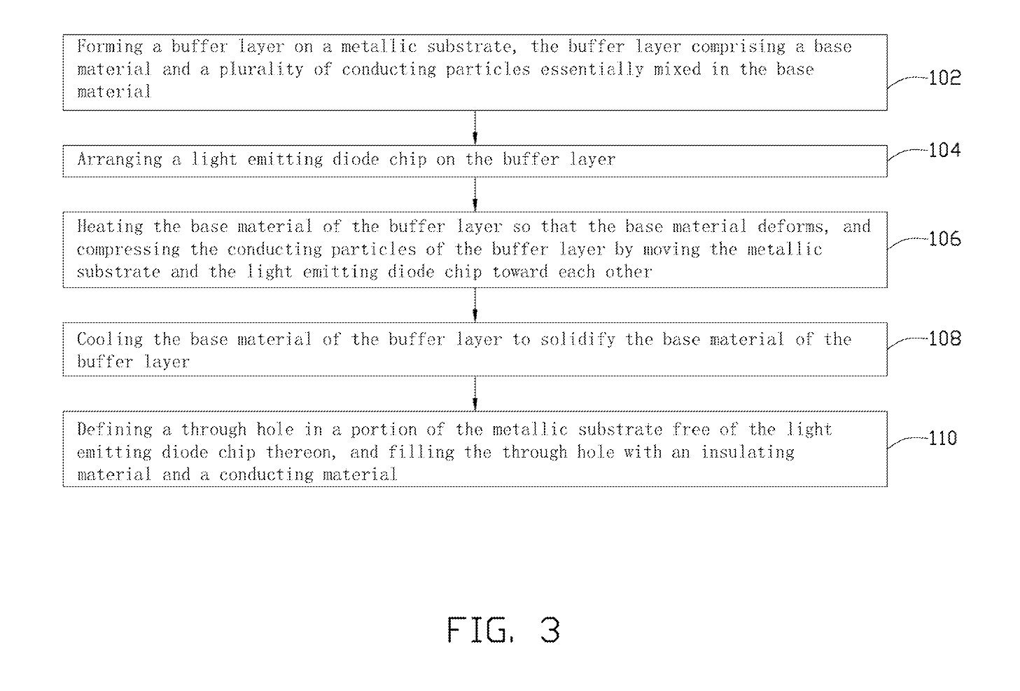

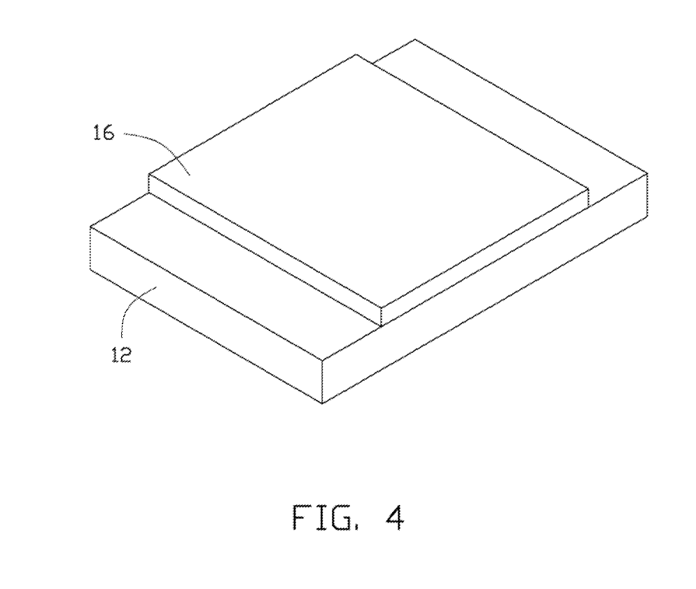

Referring to FIG. 3, the disclosure also relates to a method for manufacturing the LED package 100 in the above embodiment. Referring also to FIGS. 4 to 9, the method is summarized in detail below.

In step 102, a metallic substrate 12 and a buffer layer 16 as shown in FIG. 1 is provided, and the buffer layer 16 is formed on the metallic substrate 12 (see FIG. 4). In this embodiment, the thickness of the buffer layer 16 is in a range between about 10 μm to about 35 μm. A surface area of the buffer layer 16 is about 100 μm×100 μm. A diameter of each conducting particle 162 is in a range between about 1 μm to about 15 μm. A surface area of the metallic substrate 12 is greater than that of the buffer layer 16.

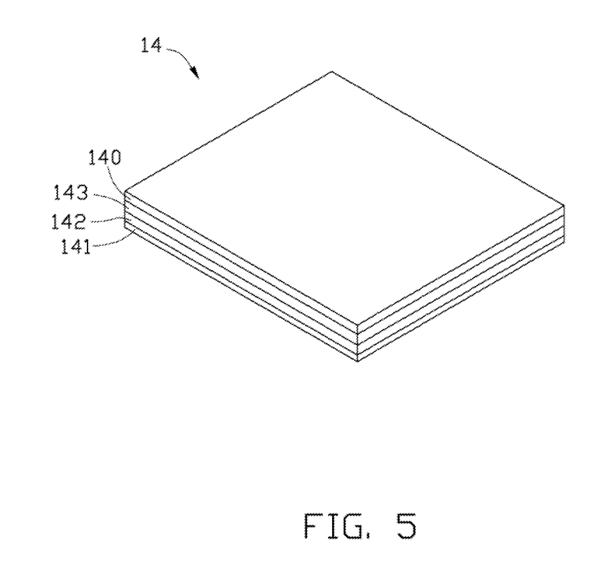

In step 104, an LED chip 14 as shown in FIG. 5, is provided and arranged on the buffer layer 16. In this embodiment, the LED chip 14 includes a sapphire substrate 140, a p-type semiconductor layer 141, an active layer 142, and an n-type semiconductor layer 143. In general, the p-type semiconductor layer 141 is arranged on the buffer layer 16 to contact with the buffer layer 16. The active layer 142 is formed on the p-type semiconductor layer 141. The n-type semiconductor layer 143 is further formed on the active layer 142 and faces away from the p-type semiconductor layer 141, and the sapphire substrate 140 is formed on the n-type semiconductor layer 143. A surface area of the LED chip 14 is generally equal to that of the buffer layer 16.

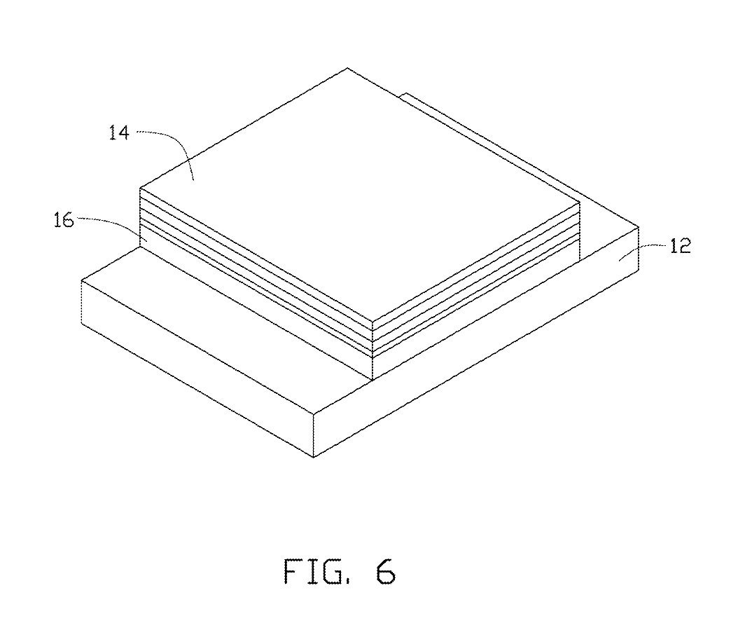

Referring also to FIG. 6, in step 106, the buffer layer 16 is heated above a certain temperature that the base material 160 of the buffer layer 16 softens, and either or both of the LED chip 14 and the metallic substrate 12 are drawn toward each other. In this way, the conducting particles 162 of the buffer layer 16 can be compressed by the LED chip 14 and the metallic substrate 12. Thus, the conducting particles 162 contact with the LED chip 14 and the metallic substrate 12. In this embodiment, the buffer layer 16 is heated above a temperature of about 200, and a compressed deformation of each of the conducting particles 162 is about 40% from its original shape when the conducting particles 162 are compressed by the LED chip 14 and the metallic substrate 12.

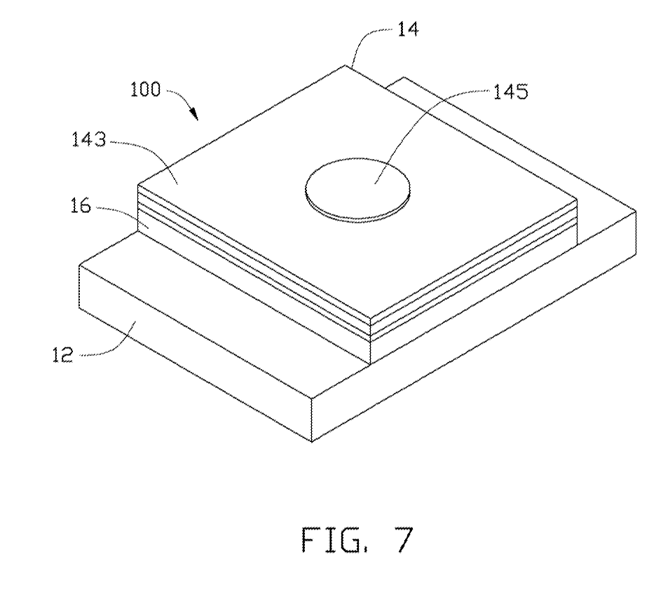

In step 108, the metallic substrate 12, the LED chip 14 and the buffer layer 16 are located at a room temperature, thus the temperature of the buffer layer 16 decreases gradually. In this embodiment, the base material 160 of the buffer layer 16 is acrylic resin, which is thermosetting resin. Thus, when the base material 160 of the buffer layer 16 is cooled to room temperature, the base material 160 become solid. In cooling the base material 160, the compression force applied on the conducting particles 162 can be maintained; thus, the conducting particles 162 can be deformed in the base material 160 when the base material 160 is completely solidified. In this manner, the conducting particles 162 fully contact with the LED chip 14 and the metallic substrate 12. In alternative embodiments, the compression force can be released during cooling the base material 160; thus the conducting particles 162 return to their spherical shape when the base material 160 is completely solidified. Furthermore, the sapphire substrate 140 can be removed by applying an etchant thereto. Moreover, an electrode pad 145 can be formed on the n-type semiconductor layer 143, as shown in FIG. 7. The electrode pad 145 can be made of gold, copper, and aluminum, or another suitable material.

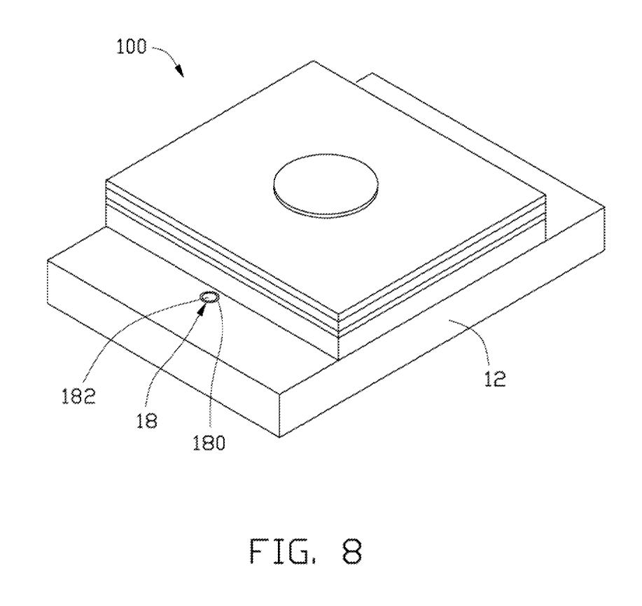

In step 110, a through hole 18 can be defined in the metallic substrate 12 at a portion thereof which is free of the LED chip 14, and an insulating material 180 and a conducting material 182 can be filled in the through hole 18. Thereby, the LED package 100 is obtained, as shown in FIG. 8. In this embodiment, the insulating material 180 is generally annular, and is located between the metallic substrate 12 and the conducting material 182 to electrically insulate the conducting material 182 from the metallic substrate 12. The through hole 18 can be cylindrical or conical. In alternative embodiments, the through hole 18 can be rectangular. The insulating material 180 can be silicon dioxide. The conducting material 182 can be copper or copper alloy.

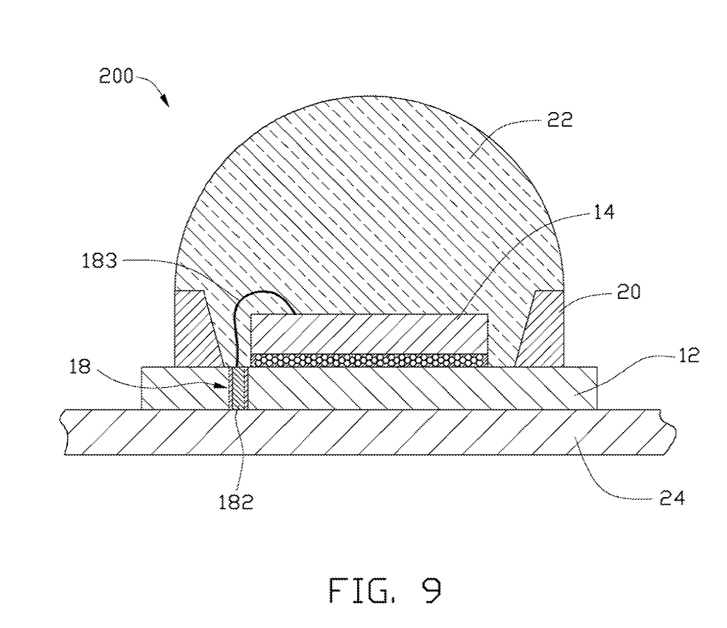

As shown in FIG. 9, the LED package 100 can be manufactured by applying other processes, thereby obtaining an LED 200. In one typical example, a wire 183 can be provided to electrically connect the electrode pad 145 to the conducting material 182 in the through hole 18 of the metallic substrate 12 by applying wire bonding or soldering. Furthermore, a molding cup 20 can be arranged on the metallic substrate 12. The molding cup 20 surrounds the LED chip 14. Moreover, an encapsulation layer 22 can be formed on the metallic substrate 12 to encapsulate the LED chip 14 and a portion of the molding cup 20. In this embodiment, a circuit board 24 is further provided, and the metallic substrate 12 is mounted on the circuit board 24. The circuit board 24 is configured for applying current to the LED chip 14.

It is understood that the above-described embodiments are intended to illustrate rather than limit the disclosure. Variations may be made to the embodiment without departing from the spirit of the disclosure. Accordingly, it is appropriate that the appended claims be construed broadly and in a manner consistent with the scope of the disclosure.

What is claimed is:

1. A light emitting diode package comprising:
a metallic substrate;
a light emitting diode chip arranged on the metallic substrate; and
a buffer layer located between and connected to the metallic substrate and the light emitting diode chip, the buffer layer comprising a base material and a plurality of conducting particles essentially mixed in the base material, the base material comprising soft epoxy, each of the conducting particles comprising a resin core and a metallic layer formed on an exterior surface of the resin core, and the conducting particles configured for electrically connecting the light emitting diode chip to the metallic substrate.

2. The light emitting diode package of claim 1, wherein each of the conducting particles is deformed.

3. The light emitting diode package of claim 1, wherein a thickness of the buffer layer is in a range between 10 μm to 35 μm.

4. The light emitting diode package of claim 1, wherein a diameter of each conducting particle is in a range between about 1 μm to about 15 μm.

5. The light emitting diode package of claim 1, wherein the metallic substrate has a surface area greater than that of the buffer layer, and a portion of the metallic substrate free of the light emitting diode chip thereon has a through hole defined therein, and the through hole has an insulating material and a conducting material filled therein, and the insulating material is located between the base material of the metallic substrate and the conducting material to electrically insulate the conducting material from the base material of the metallic substrate.

6. The light emitting diode package of claim 5, wherein the conducting material comprises one of copper and copper alloy.

7. The light emitting diode package of claim 5, wherein the insulating material comprises silicon dioxide.

8. The light emitting diode package of claim 1, wherein the metallic substrate is made of one of copper and copper alloy.

9. A method for manufacturing a light emitting diode package, comprising:
forming a buffer layer on a metallic substrate, the buffer layer comprising a base material and a plurality of conducting particles essentially mixed in the base material, the base material comprising soft epoxy, each of the conducting particles comprising a resin core and a metallic layer formed on an exterior surface of the resin core;
arranging a light emitting diode chip on the buffer layer at a side of the buffer layer facing away from the metallic substrate;
heating the base material of the buffer layer so that the base material deforms, and compressing the conducting particles of the buffer layer by driving the metallic substrate and the light emitting diode chip toward each other, such that the conducting particles contacting with the metallic substrate and the light emitting diode chip;
cooling the base material of the buffer layer to solidify the base material of the buffer layer.

10. The method of claim 9, further comprising:
defining a through hole in a portion of the metallic substrate free of the light emitting diode chip thereon, and filling the through hole with an insulating material and a conducting material, wherein the insulating material is located between the base material of the metallic substrate and the conducting material to electrically insulate the conducting material from the base material of the metallic substrate.

11. The method of claim 9, wherein a compression force applied on the conducting particles of the buffer layer is maintained when the base material of the buffer layer is solidified.
